(19) United States
(12) Patent Application Publication
(10) Pub. No.: US 2025/0015785 A1
(43) Pub. Date: Jan. 9, 2025

(54) METHOD AND DEVICE FOR DESIGNING AND OVERSAMPLED LOW DELAY FILTER BANK

(71) Applicant: DOLBY INTERNATIONAL AB, Dublin (IE)

(72) Inventor: Per EKSTRAND, Saltsjöbaden (SE)

(73) Assignee: DOLBY INTERNATIONAL AB, Dublin (IE)

(21) Appl. No.: 18/712,235

(22) PCT Filed: Nov. 29, 2022
(86) PCT No.: PCT/EP2022/083700

§ 371 Date: May 21, 2024

Related U.S. Application Data
(60) Provisional application No. 63/284,172, filed on Nov. 30, 2021.
(60) Provisional application No. 63/419,627, filed on Oct. 26, 2022.

(51) Int. Cl. H03H 17/02

(52) U.S. Cl. CPC H03H 17/0266

(57) ABSTRACT

The present document describes a method (200) for determining N coefficients of an asymmetric prototype filter p₀ for use in a low delay M-channel analysis and/or synthesis filter bank (101, 102) comprising M analysis filters hₖ (103) and/or M synthesis filters fₖ(106), k=0, . . . , M−1, wherein M is greater than 1, and wherein subband signals which are processed by the analysis and/or synthesis filter bank (101, 102) are decimated by a decimation factor S, with S<M. The method (200) comprises determining (201) a target transfer function of the analysis and/or synthesis filler bank (101, 102) comprising a target delay D; wherein D is smaller or equal to N. Furthermore. the method (200) comprises determining (202) a composite objective function eₜₒₜ comprising a transfer function error term e and an aliasing error term eₐ; wherein the transfer function error term eₜ is associated with a deviation between a transfer function of the analysis and/or synthesis filter bank (101, 102) and the target transfer function; and wherein the aliasing error term eₐ is associated with errors incurred

### CROSS-REFERENCE TO RELATED APPLICATIONS

This application claims priority from U.S. Provisional Application No. 63/284,172, filed 30 Nov. 2021, and U.S. Provisional Application No. 63/419,627, filed 26 Oct. 2022.

### TECHNICAL FIELD

The present document relates to a method and a corresponding device for designing an oversampled low delay filter bank which exhibits a precise band separation and/or a low intra-channel pass band ripple.

### BACKGROUND

A digital filter bank is a collection of two or more parallel digital filters. The analysis filter bank splits the incoming signal into a number of separate signals named subband signals or spectral coefficients. The filter bank is critically sampled or maximally decimated when the total number of subband samples per unit time is the same as that for the input signal. A so-called synthesis filter bank combines the subband signals into an output signal.

A problem in critically sampled filter bank designs is that any attempt to alter the subband samples or spectral coefficients, e.g., by applying an equalizing gain curve or by quantizing the samples, typically renders aliasing artifacts in the output signal. Therefore, filter bank designs are desirable which reduce such artifacts when the subband samples are subjected to subband processing.

A possible approach to reducing aliasing artifacts is the use of an oversampled, i.e., a not critically sampled, filter bank. However, a direct design of an oversampled filter bank may lead to impairments of the band separation between the different subbands.

The present document addresses the technical problem of providing filter banks which are robust with regards to aliasing artifacts and which exhibit a precise band separation and/or low intra-channel pass band ripple (within the individual subbands). The technical problem is solved by the independent claims. Preferred examples are described in the dependent claims.

### SUMMARY

According to an aspect, a method for determining N coefficients of an asymmetric prototype filter p₀ for building an M-channel (low delay and/or subsampled) analysis/synthesis filter bank is described. The analysis/synthesis filter bank may comprise M analysis filters hₖ and M synthesis filters fₖ, wherein k takes on values from 0 to M−1 and wherein typically M is greater than 1. The analysis/synthesis filter bank has an overall reconstruction accuracy, which is typically associated with the coefficients of the analysis and synthesis filters, as well as with the decimation and/or interpolation operations.

The M analysis filters may form an analysis filter bank, which may be used to determine M subband signals based on an input (audio) signal. The subband signals may be decimated by a decimation factor S, with S<M, thereby providing the M decimated subband signals using the analysis filter bank.

The M decimated subband signals may be processed (e.g., using one or more equalization filters and/or coefficients), thereby providing M decimated and possibly processed subband signals. These subband signals may be upsampled by the decimation factor S, and may then be processed using the M synthesis filters of the synthesis filter bank, thereby providing a processed (audio) signal. Hence, the analysis/synthesis filter bank may be an oversampled filter bank.

The method comprises the step of determining a target transfer function of the filter bank comprising a target delay D. Typically a target delay D which is smaller or equal to N is selected. The method comprises further the step of determining a composite objective function eₜₒₜ comprising a transfer function error term eₜ and an aliasing error term eₐ. The transfer function error term may be associated with the deviation between the transfer function of the filter bank and the target transfer function, and the aliasing error term eₐ may be associated with errors incurred due to the decimation and/or interpolation of the subband signals (by the decimation factor S). In a further method step, the N coefficients of the asymmetric prototype filter p₀ are determined, such that the composite objective function eₜₒₜ is reduced, in particular optimized and/or minimized.

Typically, the step of determining the objective function eₜₒₜ and the step of determining the N coefficients of the asymmetric prototype filter p₀ are repeated iteratively, until a minimum value of the objective function eₜₒₜ is reached. In particular, the objective function eₜₒₜ may be determined on the basis of a given set of coefficients of the prototype filter, and an updated set of coefficients of the prototype filter may be generated by reducing the objective function eₜₒₜ. This process may be repeated until no further reductions of the objective function may be achieved through the modification of the prototype filter coefficients. This means that the step of determining the objective function eₜₒₜ may comprise determining a value for the composite objective function eₜₒₜ for given coefficients of the prototype filter p₀ and the step of determining the N coefficients of the asymmetric prototype filter p₀ may comprise determining updated coefficients of the prototype filter p₀ based on a derivative or an estimate of the derivative (e.g., a first and/or a second derivative) of the composite objective function eₜₒₜ associated with the coefficients of the prototype filter p₀.

The composite objective function eₜₒₜ may comprise the following term:

$$a {e}_{t} + ( 1 - α ) {e}_{a} ,$$

with eₜ being the transfer function error term, eₐ being the aliasing error term and α being a weighting constant taking on values between 0 and 1. The transfer function error term eₜ may be determined by accumulating the squared deviation between the transfer function of the filter bank and the target transfer function for a plurality of frequencies. In particular, the transfer function error term eₜ may be calculated as

$${e}_{t} = \frac{1}{2 π} {\int }_{- π}^{π} {\vert \frac{1}{2} ( {A}_{0} ( {e}^{j ω} ) + {A}_{0}^{*} ( {e}^{- j ω )} ) ) - P ( ω ) {e}^{- j ω D} \vert}^{2} d ω$$

with P(ω)e^{-jωD} being the target transfer function, and

$${A}_{0} ( z ) = {\sum }_{k = 0}^{M - 1} {H}_{k} ( z ) {F}_{k} ( z )$$

wherein Hₖ(z) and Fₖ(z) are the z-transforms of the analysis and synthesis filters hₖ(n) and fₖ(n), respectively.

The aliasing error term eₐ may be determined by accumulating the squared magnitude of alias gain terms for a plurality of frequencies. In particular, the aliasing error term eₐ may be calculated as

$${e}_{a} = \frac{1}{2 π} {\sum }_{l = 1}^{S - 1} {\int }_{- π}^{π} {\vert {Ã}_{l} ( {e}^{j ω} ) \vert}^{2} d ω$$

$$with {Ã}_{l} ( z ) = \frac{1}{2} ( {A}_{l} ( z ) + {A}_{M - l *} ( z ) ) , for z = {e}^{j ω} and$$

$$with {Ã}_{l} ( z ) = \frac{1}{2} ( {A}_{l} ( z ) + {A}_{M - l *} ( z ) ) , with {A}_{l} ( z ) = {\sum }_{k = 0}^{M - 1} {H}_{k} ( {zW}^{l} ) {F}_{k} ( z )$$

being the l^{th} alias gain term evaluated on the unit circle with W=e^{-i2π/S}, wherein Hₖ(z) and Fₖ(z) are the z-transforms of the analysis and synthesis filters hₖ(n) and fₖ(n), respectively. The notation Aₗ_{_{*}}(z) indicates the z-transform of the sequence a*ₗ(n), i.e., the sequence aₗ(n) complex-conjugated.

The step of determining a value for the composite objective function eₜₒₜ may comprise generating the analysis filters hₖ(n) and the synthesis filters fₖ(n) of the analysis/synthesis filter bank based on the prototype filter p₀(n) using cosine modulation, sine modulation and/or complex-exponential modulation. In particular, the analysis and synthesis filters may be determined using cosine modulation as

$${h}_{k} ( n ) = \sqrt{2} {p}_{0} ( n ) cos \{ \frac{π}{M} ( k + \frac{1}{2} ) ( n - \frac{D}{2} ∓ \frac{M}{2} ) \}$$

with n=0 . . . N−1, for the M analysis filters of the analysis filter bank and;

$${f}_{k} ( n ) = \sqrt{2} {p}_{0} ( n ) cos \{ \frac{π}{M} ( k + \frac{1}{2} ) ( n - \frac{D}{2} \pm \frac{M}{2} ) \}$$

with n=0 . . . N−1, for the M synthesis filters of the synthesis filter bank.

The analysis and synthesis filters may also be determined using complex exponential modulation as

$${h}_{k} ( n ) = \sqrt{2} {p}_{0} ( n ) exp \{ i \frac{π}{M} ( k + \frac{1}{2} ) ( n - \frac{D}{2} - A ) \}$$

with n=0 . . . N−1, and A being an arbitrary constant, for the M analysis filters of the analysis filter bank and;

$${f}_{k} ( n ) = {p}_{0} ( n ) exp \{ i \frac{π}{M} ( k + \frac{1}{2} ) ( n - \frac{D}{2} + A ) \}$$

with n=0 . . . N−1, for the M synthesis filters of the synthesis filter bank.

The step of determining a value for the composite objective function eₜₒₜ may comprise setting at least one of the filter bank channels to zero. This may be achieved by applying zero gain to at least one analysis and/or synthesis filter, i.e., the filter coefficients hₖ and/or fₖ may be set to zero for at least one channel k. In particular, a predetermined number of the low frequency channels and/or a predetermined number of the high frequency channels may be set to zero. In other words, the low frequency filter bank channels k=0 up to C_{low}; with C_{low} greater than zero may be set to zero. Alternatively, or in addition, the high frequency filter bank channels k=C_{high} up to M−1, with C_{high} smaller than M−1 may be set to zero.

The purpose of setting a predetermined number of channels to zero is to present the filter bank to an extreme form of equalization, which in general will manifest in strong aliasing—i.e., the aliasing error term eₐ will become large in the steps of determining a value for the composite objective function eₜₒₜ. After the minimum value of the composite objective function eₜₒₜ is reached, this results in a filter bank design which reduces aliasing artifacts when the subband samples are subjected to subband processing.

In such a case, the step of determining a value for the composite objective function eₜₒₜ may comprise generating the analysis and synthesis filters for the aliasing terms carrying the largest aliasing (main aliasing) using complex exponential modulation. It may further comprise generating the analysis and synthesis filters for the remaining aliasing terms using cosine modulation. In other words, the optimization procedure may be done in a partially complex-valued manner, where the aliasing error terms which are free from main aliasing are calculated using real valued filters, e.g., filters generated using cosine modulation, and where the aliasing error terms which carry the main aliasing in a real-valued system are modified for complex-valued processing, e.g., using complex exponential modulated filters. By doing this, high quality filter banks may be generated in a computationally efficient manner.

As outlined above, a prototype filter for an oversampled filter bank may be determined. It can be shown that the oversampling operation, i.e., the use of a decimation factor S<M, during the design of the prototype filter p₀, may lead to a widening of the main lobe of the analysis and/or synthesis filters and/or to a decrease of the band separation quality of the analysis and/or synthesis filter bank (compared to a design of a critically sampled filter bank). In view of this, the composite objective function eₜₒₜ may comprise a lobe width term eₘ in addition to the transfer function error term eₜ and the aliasing error term eₐ, wherein the lobe width term may be directed at reducing the width of the main lobe of the prototype filter p₀.

The lobe width term may be dependent on the energy of the frequency response of the prototype filter p₀ within a transition frequency range indicative of the transition between two neighboring subband channels. In particular, the lobe width term may be dependent on the integral of the energy of the frequency response of the prototype filter p₀ across the transition frequency range. The transition frequency range may start at the (desired) point of intersection (i.e., the cross over frequency) between two subband channels (in other words, the point in frequency exactly in between the two midpoints in the pass bands of two neighboring subband channels). Alternatively, or in addition, the transition frequency range may end at at least twice the frequency which corresponds to the point of intersection between two subband channels. Typically, the transition frequency range does not extend into (what is considered to be) the pass band nor the stop band of the prototype filter.

The lobe width term may be dependent on or may correspond to

$${e}_{m} = \frac{1}{π} {\int }_{\frac{π}{M}}^{\frac{2 π}{M}} {\vert {P}_{0} ( {e}^{j ω} ) \vert}^{2} d ω$$

with P₀(e^{jω}) being the frequency response of the prototype filter p₀, and with

$$[ \frac{π}{M} , \frac{2 π}{M} ]$$

being a transition frequency range of the resulting analysis and/or synthesis filter bank (translated in frequency to the frequency response of the prototype filter p₀).

The composite objective function eₜₒₜ may comprise a weighted sum of the lobe width term eₘ, the transfer function error term eₜ and the aliasing error term eₐ. By making use of a lobe width term within the objective function, the band separation quality of an oversampled analysis/synthesis filter bank may be improved in an efficient and reliable manner.

The N coefficients of the asymmetric prototype filter p₀ that reduce the composite objective function eₜₒₜ may be determined using an auxiliary decimation factor which is greater than the decimation factor S that is used by the analysis and/or synthesis filter bank. In other words, during the (iterative) procedure for determining the N coefficients of the asymmetric prototype filter p₀, it may be assumed that the analysis and/or synthesis filter bank makes use of an auxiliary decimation factor which is greater than the decimation factor S, but typically smaller than M. By doing this, the band separation quality of an oversampled analysis/synthesis filter bank may be improved in an efficient and reliable manner.

The determination of an asymmetric low-delay analysis/synthesis filter bank with robust aliasing performance may lead to an increased ripple in the frequency response of the individual pass bands of the different analysis and/or synthesis filters. For this purpose, the composite objective function eₜₒₜ may comprise a ripple term eₛ in addition to the transfer function error term eₜ and the aliasing error term eₐ, wherein the ripple term may be directed at limiting and/or reducing the ripple, in particular the shoot over in vicinity of the cross over frequency, in the pass band of the prototype filter p₀.

The ripple term may be dependent on the energy of the deviation in the frequency response of the prototype filter p₀ within the pass band, notably from a scaled frequency response at the mid and/or center frequency of the pass band. In particular, the ripple term may be dependent on the integral of the energy of the deviation in the frequency response of the prototype filter p₀ across the pass band from the frequency response at the mid and/or center frequency of the pass band.

The ripple term may be dependent on or may correspond to

$${e}_{s} = \frac{1}{π} {\int }_{0}^{\frac{π}{M}} {( \vert {P}_{0} ( ω ) \vert - γ \vert {P}_{0} ( 0 ) \vert )}_{+}^{2} d ω$$

with P₀(ω) being the frequency response of the prototype filter p₀, and with

$$[ 0 , \frac{π}{M} ]$$

being a frequency range, in particular a half, of the pass band of the resulting analysis and/or synthesis filter bank (translated in frequency to the frequency response of the prototype filter p₀), with P₀(0) being the frequency response of the prototype filter p₀ at the mid and/or center frequency (ω=0) of the pass band, with γ being a scaling factor controlling the allowable amount of ripple, and with (⋅)₊ being an operator which limits the expression within the operator to positive values, i.e., all negative values are excluded from the integration.

The composite objective function eₜₒₜ may comprise a weighted sum of the ripple term eₛ, the transfer function error term eₜ and the aliasing error term eₐ. By making use of a ripple term within the objective function, the ripple within the subbands of a low-delay asymmetric analysis/synthesis filter bank may be controlled in an efficient and reliable manner.

In a preferred example, the composite objective function eₜₒₜ comprises a weighted sum of the ripple term eₛ, the transfer function error term eₜ, the aliasing error term eₐ and the lobe width term eₘ, thereby controlling the ripple within the subbands of an analysis/synthesis filter bank and the band separation quality of the analysis/synthesis filter bank in an optimized manner.

The method may comprise configuring the asymmetric prototype filter p₀ using the N coefficients, and/or applying the configured asymmetric prototype filter p₀ in a filter bank to process an audio signal. Alternatively, or in addition, the method may comprise generating the analysis filters hₖ and the synthesis filters fₖ of the analysis and/or synthesis filter bank based on the N coefficients of the prototype filter p₀, e.g., using cosine modulation, sine modulation and/or complex-exponential modulation. An audio signal may be processed using the analysis and/or synthesis filter bank.

According to a further aspect, a device and/or apparatus for determining N coefficients of an asymmetric prototype filter p₀ for use in an M-channel analysis and/or synthesis filter bank comprising M analysis filters hₖ and/or M synthesis filters fₖ, k=0, . . . , M−1, is described, wherein M is typically greater than 1, and wherein subband signals which are processed by the analysis and/or synthesis filter bank are decimated by a decimation factor S, with S<M.

The device may be configured to determine a target transfer function of the analysis and/or synthesis filter bank comprising a target delay D. Furthermore, the device may be configured to determine a composite objective function eₜₒₜ comprising a transfer function error term eₜ and an aliasing error term eₐ. The composite objective function eₜₒₜ may comprise an additional ripple term eₛ and/or an additional lobe width term eₘ. In addition, the device may be configured to determine N coefficients of the asymmetric prototype filter p₀ by reducing the composite objective function eₜₒₜ.

According to a further aspect, a system configured to process an audio signal is described, wherein the system comprises one or more processors, and a non-transitory computer-readable medium storing instructions that, when executed by the one or more processors, cause the one or more processors to perform operations of a method described herein.

According to another aspect, a method for processing an audio signal is described. The method comprises determining a plurality of subband signals by filtering the audio signal with M analysis filters of an oversampled analysis filter bank, processing the plurality of subband signals to generate a plurality of processed subband signals, and determining a processed audio signal by filtering the plurality of processed subband signals with M synthesis filters of an oversampled synthesis filter bank. The M analysis filters and the M synthesis filters may be modulated versions of an asymmetric prototype filter p₀ determined using the method described herein.

According to a further aspect, an audio signal processing device for processing an audio signal is described. The audio processing device is configured to determine a plurality of subband signals by filtering the audio signal with M analysis filters of an oversampled analysis filter bank; to process the plurality of subband signals to generate a plurality of processed subband signals; and to determine a processed audio signal by filtering the plurality of processed subband signals with M synthesis filters of an oversampled synthesis filter bank.

It should be noted that the methods described herein may each be implemented in software and/or computer readable code on one or more processors, in whole or in part of the respective methods.

According to a further aspect, a software program is described. The software program may be adapted for execution on a processor and for performing the method steps outlined in the present document when carried out on the processor.

According to another aspect, a storage medium is described. The storage medium may comprise a software program adapted for execution on a processor and for performing the method steps outlined in the present document when carried out on the processor.

According to a further aspect, a computer program product is described. The computer program may comprise executable instructions for performing the method steps outlined in the present document when executed on a computer.

According to a further aspect, a non-transitory computer-readable medium is described, storing instructions that, when executed by one or more processors, cause the one or more processors to perform operations of any of the methods described herein.

It should be noted that the methods and systems including its preferred embodiments as outlined in the present patent application may be used stand-alone or in combination with the other methods and systems disclosed in this document. Furthermore, all aspects of the methods and systems outlined in the present patent application may be arbitrarily combined. In particular, the features of the claims may be combined with one another in an arbitrary manner.

### SHORT DESCRIPTION OF THE FIGURES

The invention is explained below in an exemplary manner with reference to the accompanying drawings, wherein

FIG. 1 shows an example decimated filter bank with M channels or subbands using a decimation factor S; and

FIG. 2 shows a flow chart of an example method for processing audio using a filter bank.

### DETAILED DESCRIPTION

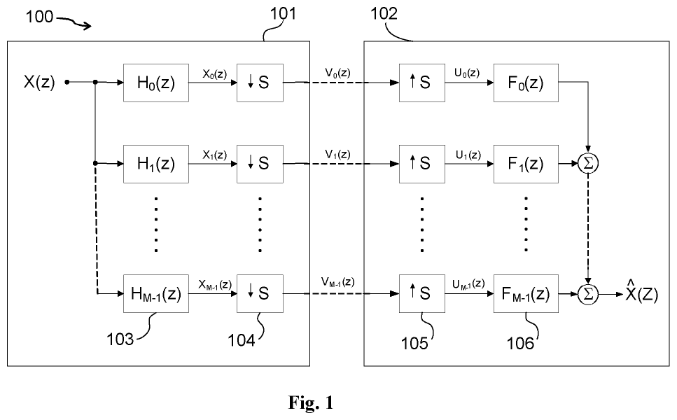

As indicated above, the present document is directed at designing a low delay oversampled filter bank which is robust with regards to aliasing artifacts, which exhibits a precise separation between the different subbands or channels and/or which exhibits low pass band ripple. In this context, FIG. 1 shows a decimated filter bank with M channels or subbands using a decimation factor S.

The analysis part 101 of the filter bank 100 produces from the input signal X(z) the subband signals Vₖ(z), which constitute the signals to be transmitted, stored, processed and/or modified. The synthesis part 102 recombines the (possibly processed and/or modified) signals Vₖ(z) to the output signal \hat{X}(z). In this layout the signals Vₖ(z) are decimated (down-sampled) by a factor S. When S=M, the filter bank is maximally decimated or critically sampled. However, to allow for e.g., low delay implementations, having significantly reduced reconstruction errors emerging from aliasing (see below), smaller values of S (S<M) may be used, hence resulting in an oversampled filter bank 100. This comes at a price of higher computational complexity for the analysis and synthesis filter banks 101, 102 as calculations are performed at a higher pace or rate than for a critically sampled filter bank. Also, less down-sampling means more subband data (i.e., samples of the subband signals Vₖ(z)) per time-unit to store or process. However, filter bank designs with S<M can nevertheless be an attractive alternative in certain scenarios.

The recombination of the subband signals Vₖ(z) to obtain the approximation \hat{X}(z) of the original signal X(z) is subject to several potential errors. The errors may be due to an approximation of the perfect reconstruction property, and may include non-linear impairments due to aliasing, which may be caused by the decimation and the interpolation of the subbands. Other errors resulting from approximations of the perfect reconstruction property may be due to linear impairments such as phase and amplitude distortion.

Following the notations of FIG. 1, the outputs of the different analysis filters Hₖ(z) 103 are given by

$${X}_{k} ( z ) = {H}_{k} ( z ) X ( z ) , \qquad ( 1 )$$

where k=0, . . . , M−1. The decimators 104, also referred to as down-sampling units, give the outputs

$${V}_{k} ( z ) = \frac{1}{S} {\sum }_{l = 0}^{S - 1} {x}_{k} ( {z}^{1 / S} {W}^{l} ) = \frac{1}{S} {\sum }_{l = 0}^{S - 1} {H}_{k} ( {z}^{1 / S} {W}^{l} ) \times ( {z}^{1 / S} {W}^{l} ) , \qquad ( 2 )$$

where W=e^{-2π/S}. The outputs of the interpolators 105, also referred to as up-sampling units, are given by

$${U}_{k} ( z ) = {V}_{k} ( {z}^{S} ) = \frac{1}{S} {\sum }_{l = 0}^{S - 1} {H}_{e} ( z {W}^{l} ) \times ( {zW}^{l} ) , \qquad ( 3 )$$

and using Eq. (3) the sum of the signals obtained from the different synthesis filters 106 can be written as

$$\hat{X} ( z ) = {\sum }_{k = 0}^{M - 1} {F}_{k} ( z ) {U}_{k} ( z ) = \frac{1}{S} {\sum }_{l = 0}^{S - 1} X ( z {W}^{l} ) {A}_{l} ( z ) \qquad ( 4 )$$

$$where$$

$${A}_{l} ( z ) = {\sum }_{k = 0}^{M - 1} {H}_{k} ( z {W}^{l} ) {F}_{k} ( z ) \qquad ( 5 )$$

is the gain for the l^{th} alias term X(xW^{l}). Eq. (4) shows that the output signal \hat{X}(z) is a sum of S components consisting of the product of the modulated input signal X (zW') and the corresponding alias gain term Aₗ(z). Eq. (4) can be rewritten as

$$\hat{X} ( z ) = \frac{1}{S} \{ X ( z ) {A}_{0} ( z ) + {\sum }_{l = 1}^{S - 1} X ( z {W}^{l} ) {A}_{l} ( z ) \} . \qquad ( 6 )$$

The last sum on the right-hand side (RHS) of Eq. (6) constitutes the sum of all non-wanted alias terms. Canceling all aliasing, that is forcing this sum to zero by means of proper choices of Hₖ(z) and Fₖ(z), gives

$$\hat{X} ( z ) = \frac{1}{s} X ( z ) {A}_{0} ( z ) = X ( z ) T ( z ) , \qquad ( 7 )$$

$$where$$

$$T ( z ) = \frac{1}{S} {\sum }_{k = 0}^{M - 1} {H}_{k} ( z ) {F}_{k} ( z ) \qquad ( 8 )$$

is the overall transfer function or distortion function. Eq. (8) shows that, depending on Hₖ(z) and Fₖ(z), T(z) could be free from both phase distortion and amplitude distortion. The overall transfer function would in this case simply be a delay of D samples with a constant scale factor c, i.e.

$$T ( z ) = c {z}^{- D} , \qquad ( 9 )$$

which substituted into Eq. (7) gives

$$\hat{X} ( z ) = c {z}^{- D} X ( z ) . \qquad ( 10 )$$

The type of filters that satisfy Eq. (10) are said to have the perfect reconstruction (PR) property. If Eq. (10) is not perfectly satisfied, albeit satisfied approximately, the filters are of the class of approximate perfect reconstruction filters.

In the following, a method for designing analysis and synthesis filter banks 101, 102 from a prototype filter is described. The resulting filter banks are referred to as cosine modulated filter banks. In the traditional theory for cosine modulated filter banks, the analysis filters hₖ(n) and synthesis filters fₖ(n) are cosine modulated versions of a symmetric low-pass prototype filter p₀(n), i.e.

$${h}_{k} ( n ) = \sqrt{2} {p}_{0} ( n ) cos \{ \frac{π}{M} ( k + \frac{1}{2} ) ( n - \frac{N}{2} ∓ \frac{M}{2} ) \} , 0 \leq n \leq N , 0 \leq k < M \qquad ( 11 )$$

$${f}_{k} ( n ) = \sqrt{2} {p}_{0} ( n ) cos \{ \frac{π}{M} ( k + \frac{1}{2} ) ( n - \frac{N}{2} \pm \frac{M}{2} ) \} , 0 \leq n \leq N , 0 \leq k < M \qquad ( 12 )$$

respectively, where M is the number of channels of the filter bank 100 and N is the prototype filter order.

The above cosine modulated analysis filter bank 101 produces real-valued subband samples for real-valued input signals. If the subband samples are down sampled using a factor S=M, the system is critically sampled. Depending on the choice of the prototype filter, the filter bank may constitute an approximate perfect reconstruction system, notably a so-called pseudo QMF bank, or a perfect reconstruction (PR) system. The overall delay, or system delay, for a traditional cosine modulated filter bank using a symmetric prototype filter is N.

In order to obtain filter bank systems having lower system delays, the symmetric prototype filters used in conventional filter banks may be replaced by asymmetric prototype filters. In the prior art, the design of asymmetric prototype filters has been restricted to systems having the perfect reconstruction (PR) property. However, the perfect reconstruction constraint imposes limitations to a filter bank used in e.g., an equalization system, due to the limited degrees of freedom when designing the prototype filter. It should be noted that symmetric prototype filters have a linear phase, i.e., they have a constant group delay across all frequencies. On the other hand, asymmetric filters typically have a non-linear phase, i.e., they have a group delay which may vary with frequency.

In filter bank systems using asymmetric prototype filters, the analysis and synthesis filters may be written as

$${h}_{k} ( n ) = \sqrt{2} {p}_{0} ( n ) cos \{ \frac{π}{M} ( k + \frac{1}{2} ) ( n - \frac{D}{2} ∓ \frac{M}{2} ) \} , 0 \leq n < N , 0 \leq k < M \qquad ( 13 )$$

$${f}_{k} ( n ) = \sqrt{2} {p}_{0} ( n ) cos \{ \frac{π}{M} ( k + \frac{1}{2} ) ( n - \frac{D}{2} \pm \frac{M}{2} ) \} , 0 \leq n < N , 0 \leq k < M \qquad ( 14 )$$

respectively, where p₀(n) is the prototype filter of length N, and where D is the total delay of the filter bank system.

It should be noted, however, that when using the filter design schemes outlined in the present document, filter banks using different analysis and synthesis prototype filters may be determined.

One inherent property of the cosine modulation is that every filter has two pass bands; one in the positive frequency range and one corresponding pass band in the negative frequency range. It can be verified that the so-called main, or significant, alias terms emerge from an overlap in frequency between either the filters negative pass bands with frequency modulated versions of the positive pass bands, or reciprocally, the filters positive pass bands with frequency modulated versions of the negative pass bands. The last terms in Eqs. (13) and (14), i.e. the terms

$$∓ \frac{π}{2} ( k + \frac{1}{2} ) ,$$

are selected so as to provide cancellation of the main alias terms in cosine modulated filter banks. Nevertheless, when modifying the subband samples, the cancelation of the main alias terms is impaired, thereby resulting in a relatively strong impact of aliasing from the main alias terms. It is therefore desirable to remove these main alias terms from the subband samples altogether.

The removal of the main alias terms may be achieved by the use of so-called Complex-Exponential Modulated Filter Banks which are based on an extension of the cosine modulation to complex-exponential modulation. Such extension yields the analysis filters hₖ(n) as

$${h}_{k} ( n ) = {p}_{0} ( n ) exp \{ i \frac{π}{M} ( k + \frac{1}{2} ) ( n - \frac{D}{2} ∓ \frac{M}{2} ) \} , 0 \leq n < N , 0 \leq k < M \qquad ( 15 )$$

using the same notation as before. This can be viewed as adding an imaginary part to the real-valued filter bank, where the imaginary part consists of sine modulated versions of the same prototype filter. Considering a real-valued input signal, the output from the filter bank 101 can be interpreted as a set of subband signals (for a corresponding set of subband channels), where the real and the imaginary parts are Hilbert transforms of each other. The resulting subbands are thus (approximately) the analytic signals of the real-valued output obtained from the cosine modulated filter bank. However, this is not valid for subband channels 0 and M−1, as the frequency responses of these channels transition into negative frequencies. Depending on the filter bank design, also other subband channels may have frequency responses that transition into negative frequencies (such as a complex-exponential modulated Modified Discrete Cosine Transform, CMDCT), but for a well-designed complex-exponential modulated pseudo Quadrature Mirror Filter (CQMF) bank that has channel frequency responses that mainly overlap with its closest neighbors, the above statement may be true. Due to the complex-valued representation, the subband signals are over-sampled by at least a factor two (depending on the choice of S).

The synthesis filters are extended in the same way as

$${f}_{k} ( n ) = {p}_{0} ( n ) exp \{ i \frac{π}{M} ( k + \frac{1}{2} ) ( n - \frac{D}{2} \pm \frac{M}{2} ) \} , 0 \leq n < N , 0 \leq k < M . \qquad ( 16 )$$

Eqs. (15) and (16) imply that the output from the synthesis bank is complex-valued. Using matrix notation, where Cₐ is a matrix with the cosine modulated analysis filters from Eq. (13), and Sₐ is a matrix with the sine modulation of the same argument, the filters of Eq. (15) are obtained as Cₐ+jSₐ. In these matrices, k is the row index and n the column index. Analogously, the matrix Cₛ has synthesis filters from Eq. (14), and Sₛ is the corresponding sine modulated version. Eq. (16) can thus be written Cₛ+jSₛ, where k is the column index and n the row index. Denoting the input signal x, the output signal y is found from

$$y = ( {C}_{s} + {jS}_{s} ) ( {C}_{a} + {jS}_{a} ) x = ( {C}_{s} {C}_{a} - {S}_{s} {S}_{a} ) x + j ( {C}_{s} {S}_{a} + {S}_{s} {C}_{a} ) x \qquad ( 17 )$$

As seen from Eq. (17), the real part comprises two terms; the output from the cosine modulated filter bank and an output from a sine modulated filter bank. It can be verified that if a cosine modulated filter bank has the PR property, then its sine modulated version, with a change of sign, constitutes a PR system as well. Thus, by taking the real part of the output, the complex-exponential modulated system offers the same reconstruction accuracy as the corresponding cosine modulated system.

The complex-exponential modulated system may be extended to handle also complex-valued input signals. By extending the number of channels to 2M, i.e., by adding the filters for negative frequencies, and by keeping the imaginary part of the output signal, a pseudo QMF or a PR system for complex-valued signals is obtained.

It should be noted that the complex-exponential modulated filter bank has one pass band only for every filter in the positive frequency range. Hence, it is free from the main alias terms. The absence of main alias terms makes the aliasing cancellation constraint from the cosine (or sine) modulated filter bank system obsolete in the complex-exponential modulated system. The analysis and synthesis filters can thus be given as

$${h}_{k} ( n ) = {p}_{0} ( n ) exp \{ i \frac{π}{M} ( k + \frac{1}{2} ) ( n - \frac{D}{2} - A ) \} , 0 \leq n < N , 0 \leq k < M \qquad ( 18 )$$

$$and$$

$${f}_{k} ( n ) = {p}_{0} ( n ) exp \{ i \frac{π}{M} ( k + \frac{1}{2} ) ( n - \frac{D}{2} + A ) \} , 0 \leq n < N , 0 \leq k < M \qquad ( 19 )$$

where A is an arbitrary (possibly zero) constant, and as before, M is the number of channels, Nis the prototype filter length, and D is the system delay. By using different values of A, more efficient implementations of the analysis and synthesis filter banks 101, 102, i.e., implementations with reduced complexity, can be obtained.

Before presenting a method for an optimization of prototype filters, the disclosed approaches to the design of filter banks are summarized. Based on symmetric or asymmetric prototype filters, filter banks may be generated e.g., by modulating the prototype filters using a cosine function or a complex-exponential function. The prototype filters for the analysis and synthesis filter banks may either be different or identical. When using complex-exponential modulation, the main alias terms vanish, thereby reducing the aliasing sensitivity to modifications of the subband signals of the resulting filter banks. Furthermore, when using asymmetric prototype filters, the overall system delay of the filter banks may be reduced. It has also been shown that when using complex-exponential modulated filter banks, the output signal from a real valued input signal may be determined by taking the real part of the complex-valued output signal of the filter bank.

In the following a method for an optimization of the prototype filters is described in detail. Depending on the needs, the optimization may be directed at increasing the reconstruction accuracy, i.e., at reducing the combination of aliasing and linear distortions, at reducing the sensitivity to aliasing, at reducing the system delay, at reducing phase distortion, and/or at reducing linear distortion. In order to optimize the prototype filter p₀(n), first expressions for the alias gain terms are determined. In the following, the alias gain terms for a complex exponential modulated filter bank are derived. It should be noted, however, that the alias gain terms outlined are also valid for a cosine modulated (real valued) filter bank.

Referring to Eq. (4), the z-transform of the real part of the output signal \hat{x} (n) is

$$Z \{ Re ( \hat{x} ( n ) ) \} = {\hat{X}}_{R} ( z ) = \frac{\hat{X} ( z ) + {\hat{X}}_{*} ( z )}{2} . \qquad ( 20 )$$

The notation \hat{X}_{*}(z) is the z-transform of the sequence \hat{x}(n) complex-conjugated. From Eq. (4) and Eq. (20), it follows that the z-transform of the real part of the output signal is

$${\hat{X}}_{R} ( z ) = \frac{1}{S} {\sum }_{l = 0}^{S - 1} \frac{1}{2} ( X ( {zW}^{l} ) {A}_{l} ( z ) + X ( {zW}^{- l} ) {A}_{l *} ( z ) ) , \qquad ( 21 )$$

where it was used that the input signal x(n) is real-valued, i.e., X_{*}(zW^{l})=X(zW^{-l}). Eq. (21) may after rearrangement be written

$${\hat{X}}_{R} ( z ) = \frac{1}{S} ( X ( z ) {\tilde{A}}_{0} ( z ) + {\sum }_{l = 1}^{S - 1} X ( {zW}^{l} ) {\tilde{A}}_{l} ( z ) ) \qquad ( 22 )$$

$$where$$

$${\tilde{A}}_{l} ( z ) = \frac{1}{2} ( {A}_{l} ( z ) + {A}_{S - {l}_{*}} ( z ) ) , 0 \leq l < S \qquad ( 23 )$$

$$and W = {e}^{- i 2 π / S} .$$

Eq. (23) denotes the alias gain terms used in the optimization scheme. It can be observed from Eq. (23) that

$${\tilde{A}}_{S - l} ( z ) = \frac{1}{2} ( {A}_{S - l} ( z ) + {A}_{{l}_{*}} ( z ) ) = {\tilde{A}}_{l *} ( z ) . \qquad ( 24 )$$

Specifically, for real-valued systems

$${A}_{S - {l}_{*}} ( z ) = {A}_{l} ( z ) \qquad ( 25 )$$

which simplifies Eq. (23) into

$${\tilde{A}}_{l} ( z ) = {A}_{l} ( z ) , 0 \leq l < S . \qquad ( 26 )$$

For improved alias term minimization of an asymmetric prototype filter, for use in a M-channel filter bank system with a down-sampling factor S<M, a preferred objective function may be denoted

$${e}_{tot} ( α ) = α {e}_{t} + ( 1 - α ) {e}_{a} , \qquad ( 27 )$$

where the total error eₜₒₜ(α) is a weighted sum of the transfer function error eₜ and the aliasing error eₐ. The first alias gain term on the right hand side (RHS) of Eq. (22) evaluated on the unit circle, i.e. for z=e^{jω}, can be used to provide a measure of the error energy eₜ of the transfer function as

$${e}_{t} = \frac{1}{2 π} {\int }_{- π}^{π} {\vert \frac{1}{2} ( {A}_{0} ( {e}^{j ω} ) + {{A}_{0}}^{*} ( {e}^{- j ω} ) ) - P ( ω ) {e}^{- j ω D} \vert}^{2} d ω , \qquad ( 28 )$$

where P(ω) is a symmetric real-valued function defining the pass band and stop band ranges, and D is the total system delay. In other words, P(ω) describes the desired magnitude transfer function. In a preferred example, P(ω)=1. In the most general case, such transfer function comprises a magnitude which is a function of the frequency w. For a real-valued system Eq. (28) simplifies to

$${e}_{t} = \frac{1}{2 π} {\int }_{- π}^{π} {\vert {A}_{0} ( {e}^{j ω} ) - P ( ω ) {e}^{- j ω D} \vert}^{2} d ω \qquad ( 29 )$$

The target function P(ω) and the target delay D may be selected as an input parameter to the optimization procedure. The expression P(ω)e^{-jωD} may be referred to as the target transfer function.

A measure of the energy of the total aliasing eₐ may be calculated by evaluating the sum of the alias gain terms on the right hand side (RHS) of Eq. (22), i.e. the second term of Eq. (22), on the unit circle as

$${e}_{a} = \frac{1}{2 π} {\sum }_{l = 1}^{S - 1} {\int }_{- π}^{π} {\vert {\tilde{A}}_{l} ( {e}^{j ω} ) \vert}^{2} d ω \qquad ( 30 )$$

Overall, an optimization procedure for determining a prototype filter p₀(n) may be based on the minimization of the error of Eq. (27). The parameter a may be used to distribute the emphasis between the linear transfer function and the sensitivity to aliasing of the prototype filter. While increasing the parameter α towards 1 will put more emphasis on the transfer function error eₜ, reducing the parameter α towards 0 will put more emphasis on the aliasing error eₐ. The parameters P(ω) and D may be used to set a target transfer function of the resulting filter bank, i.e., to define the pass band and stop band behavior and to define the overall system delay.

A subset of the filter bank channels k may be set to zero, e.g., the upper half of the filter bank channels may be given zero gain. Consequently, the filter bank is triggered to generate a great amount of aliasing. This aliasing will be subsequently minimized by the optimization process. In other words, by setting a certain number of filter bank channels to zero, aliasing will be induced in order to generate an aliasing error eₐ which may be minimized during the optimization procedure. By doing this, a filter bank may be designed which is particularly robust to aliasing. Furthermore, computational complexity of the optimization process may be reduced by setting some of the filter bank channels to zero.

In cases where a down-sampling factor S, with S<M, is used, the optimization scheme which is described herein, may result in prototype filters having widened main lobes, thereby deteriorating the band separation of the resulting filter bank compared to a S=M system design. In such cases, an additional metric may be added to the error function Eq. (27), such as a penalty function which comprises or consists of an integral of the prototype filter frequency response energy over a frequency range that corresponds to the transition band, e.g.,

$${e}_{m} = \frac{1}{π} {\int }_{\frac{π}{M}}^{\frac{2 π}{M}} {\vert {P}_{0} ( {e}^{j ω} ) \vert}^{2} d ω \qquad ( 31 )$$

To incorporate the metric of Eq. (32), Eq. (27) may be changed to e.g.,

$${e}_{tot} ( α ) = α {e}_{t} + ( 1 - α ) {e}_{a} + β {e}_{m} \qquad ( 32 )$$

with β being a (relatively small) weighting coefficient.

Another approach to alleviating the broadened main lobe may be to use an increased value for the down-sampling factor S during the optimization phase of the prototype filter (and thereby decreasing the main lobe of the prototype filter), compared to the value of the down-sampling factor S that will be used during actual deployment of the filter bank 100.

Optimizing latency-constrained asymmetric prototype filters with a relatively high emphasis on limiting the aliasing of the resulting filter bank may result in a prototype filter, and hence in modulated filter bank channels, having a relatively large over shoot in the frequency response towards the cross over frequency point with the neighboring channel (instead of having a rounded main lobe in the frequency response, which tapers off from the mid frequency). To prevent this effect, an additional penalty term may be added to the total error function, wherein the additional penalty term allows for a certain amount of over shoot compared to the filter response at the mid frequency (i.e., ω=0 for the prototype filter P₀(ω)), and which heavily penalizes gain responses above the allowed over shoot. An example penalty term is given by

$${e}_{s} = \frac{1}{π} {\int }_{0}^{\frac{π}{M}} {( \vert {P}_{0} ( ω ) \vert - γ \vert {P}_{0} ( 0 ) \vert )}_{+}^{2} d ω \qquad ( 33 )$$

where γ is a positive constant which is indicative of the allowed over shoot and where the notation (⋅)₊ indicates that only positive arguments (⋅) are taken into account, i.e., negative values are neglected. Again, to incorporate the metric of Eq. (33), Eq. (32) may be changed to

$${e}_{tot} ( α ) = α {e}_{t} + ( 1 - α ) {e}_{a} + β {e}_{m} + δ {e}_{s} \qquad ( 34 )$$

with δ being a weighting coefficient that may be relatively large compared to β to strictly prevent amplitude over shoot values above γ|P₀(0)|.

In an example, the steps for filtering a time domain signal through a complex-modulated filter bank having M channels, using a prototype filter of filter length N, with a system delay D, and optimized for a certain down-sampling factor S, may be described as follows:
In order to operate the filter bank in an efficient manner, the prototype filter p₀(n), n=0, . . . . N−1, may be arranged in the poly-phase representation, where every other of the polyphase filter coefficients are negated and all coefficients are time-flipped as

$${p}_{0}^{′} ( N - 1 - 2 Mm - n ) = {( - 1 )}^{m} {p}_{0} ( 2 Mm + n ) , \qquad ( 35 )$$

$$0 \leq n < 2 M , 0 \leq m < N / ( 2 M )$$

The analysis stage begins with the poly-phase representation of the filter being applied to the time domain signal x(n) to produce a vector xₗ(n) of length 2M as

$${x}_{2 M - 1 - l} ( n ) = {\sum }_{m = 0}^{\frac{N}{2 M} - 1} {p}_{0}^{′} ( 2 Mm + l ) x ( 2 Mm + l + Sn ) , \qquad ( 36 )$$

$$0 \leq l < 2 M , n = 0 , 1 , ...$$

xₗ(n) is subsequently multiplied with a modulation matrix as

$${v}_{k} ( n ) = {\sum }_{l = 0}^{2 M - 1} {x}_{l} ( n ) exp ( j \frac{π}{2 M} ( k + \frac{1}{2} ) ( 2 l - D - M ) ) , \qquad ( 37 )$$

$$0 \leq k < M ,$$

where vₖ(n), k=0 . . . M−1, constitute the subband signals. The time index n is consequently given in subband samples.
The complex-valued subband signals can then be modified and/or processed, e.g., according to some desired, possibly time-varying and complex-valued, equalization curve gₖ(n), as

$${v}_{k}^{( m )} ( n ) = {g}_{k} ( n ) {v}_{k} ( n ) , 0 \leq k < M . \qquad ( 38 )$$

The synthesis stage starts with a demodulation step of the modified subband signals as

$${u}_{l} ( n ) = \frac{1}{M} {\sum }_{k = 0}^{M - 1} Re \{ {v}_{k}^{( m )} ( n ) exp ( j \frac{π}{2 M} ( k + \frac{1}{2} ) ( 2 l - D + M ) ) \} , \qquad ( 39 )$$

$$0 \leq l < 2 M .$$

It should be noted that the modulation steps of Eqs. (37) and (39) may be accomplished in a computationally efficient manner with algorithms using fast Fourier transform (FFT) kernels.
The demodulated samples are filtered with the poly-phase representation of the prototype filter and accumulated to the output time domain signal \hat{x}(n) according to

$$\hat{x} ( 2 Mm + l + Sn ) = \hat{x} ( 2 Mm + l + Sn ) + {p}_{0}^{′} ( N - 1 - 2 Mm - l ) {u}_{l} ( n ) , \qquad ( 40 )$$

$$0 \leq l < 2 M , 0 \leq m < N / ( 2 M ) , n = 0 , 1 , ...$$

where \hat{x}(n) is set to 0 for all n at start-up time.

The filter bank described above may be applied to channel-based or object-based audio processing, including audio encoding, transmission, and/or decoding, where one or more input audio signals are encoded to produce an encoded output, or where one or more encoded inputs are decoded to produce an output audio signal.

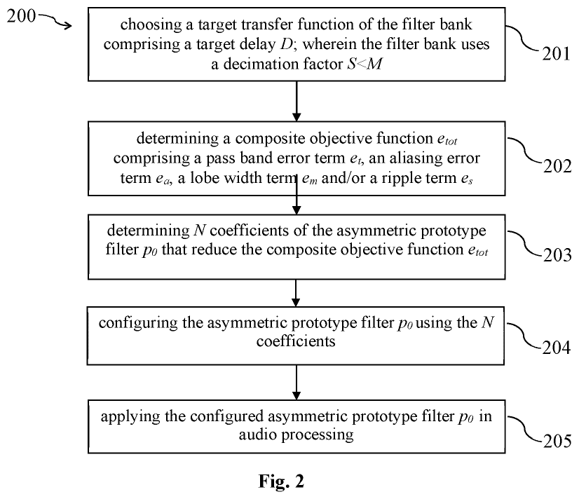

FIG. 2 is flowchart of an example method 200 for processing audio using an oversampled low-delay filter bank 100. The method 200 may be performed by a system including one or more computer processors. One or more steps shown in the flowchart may be optional steps.

The method 200 may be directed at determining N coefficients of an asymmetric prototype filter p₀ for use in an M-channel (oversampled) analysis and/or synthesis filter bank 101, 102. The filter bank 100 may comprise M analysis filters hₖ 103 and/or M synthesis filters fₖ 106, k=0, . . . , M−1, wherein M is greater than 1. The M analysis filters hₖ 103 and/or M synthesis filters fₖ 106 may be determined from modulated versions of the asymmetric prototype filter p₀. The subband signals which are processed by the analysis and/or synthesis filter bank 101, 102 may be decimated by a decimation factor S, with S<M.

The method 200 comprises determining 201 a target transfer function of the analysis and/or synthesis filter bank 101, 102 comprising a target delay D, wherein D is typically smaller or equal to N. The target function may have been set by a user of the method 200 (e.g., via a user interface).

The method 200 further comprises determining 202 a composite objective function eₜₒₜ which may comprise a transfer function error term eₜ and/or an aliasing error term eₐ. Furthermore, the composite objective function eₜₒₜ may comprise a ripple term eₛ and/or a lobe width term eₘ. In particular, a value and/or a derivative (e.g., a gradient) of the composite objective function eₜₒₜ may be determined.

The transfer function error term eₜ is typically associated with a deviation between the transfer function of the analysis and/or synthesis filter bank 101, 102 and the target transfer function. The aliasing error term eₐ is typically associated with errors incurred due to the decimation (by down-sampling units 104) and interpolation (by up-sampling units 105) of the subband signals which are processed by the analysis and/or synthesis filter bank 101, 102.

Furthermore, the method 200 comprises determining 203 N coefficients of the asymmetric prototype filter p₀ such that the composite objective function eₜₒₜ is reduced, in particular minimized. In addition, the method 200 may comprise configuring 204 the asymmetric prototype filter p₀ using the N coefficients, and/or applying 205 the configured asymmetric prototype filter p₀ (and/or the analysis filters 103 and/or synthesis filters 106) to an audio signal.

Aspects of the systems described herein may be implemented in an appropriate computer-based sound processing network environment for processing digital or digitized audio files. Portions of the adaptive audio system may include one or more networks that comprise any desired number of individual machines, including one or more routers (not shown) that serve to buffer and route the data transmitted among the computers. Such a network may be built on various different network protocols, and may be the Internet, a Wide Area Network (WAN), a Local Area Network (LAN), or any combination thereof.

One or more of the components, blocks, processes or other functional components may be implemented through a computer program that controls execution of a processor-based computing device of the system. It should also be noted that the various functions disclosed herein may be described using any number of combinations of hardware, firmware, and/or as data and/or instructions embodied in various machine-readable or computer-readable media, in terms of their behavioral, register transfer, logic component, and/or other characteristics. Computer-readable media in which such formatted data and/or instructions may be embodied include, but are not limited to, physical (non-transitory), non-volatile storage media in various forms, such as optical, magnetic or semiconductor storage media.

While one or more implementations have been described by way of example and in terms of the specific embodiments, it is to be understood that one or more implementations are not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

Various aspects and implementations of the present invention may also be appreciated from the following enumerated example embodiments (EEEs), which are not claims.
EEE1. A method (200) for determining N coefficients of an asymmetric prototype filter p₀ for use in an M-channel analysis and/or synthesis filter bank (101, 102) comprising M analysis filters hₖ (103) and/or M synthesis filters fₖ (106), k=0, . . . , M−1, wherein M is greater than 1, and wherein subband signals which are processed by the analysis and/or synthesis filter bank (101, 102) are decimated by a decimation factor S, with S<M, the method (200) comprising
   determining (201) a target transfer function of the analysis and/or synthesis filter bank (101, 102) comprising a target delay D; wherein D is smaller or equal to N;
   determining (202) a composite objective function eₜₒₜ comprising a transfer function error term eₜ and an aliasing error term eₐ; wherein the transfer function error term eₜ is associated with a deviation between a transfer function of the analysis and/or synthesis filter bank (101, 102) and the target transfer function; and wherein the aliasing error term eₐ is associated with errors incurred due to the decimation and/or interpolation of the subband signals which are processed by the analysis and/or synthesis filter bank (101, 102); and
   determining (203) N coefficients of the asymmetric prototype filter p₀ that reduce, in particular minimize, the composite objective function eₜₒₜ.
EEE2. The method (200) of EEE1, wherein
   the composite objective function eₜₒₜ comprises a lobe width term eₘ in addition to the transfer function error term eₜ and the aliasing error term eₐ; and
   the lobe width term is directed at reducing a width of a main lobe of the prototype filter p₀.
EEE3. The method (200) of EEE2, wherein
   the lobe width term is dependent on an energy of a frequency response of the prototype filter p₀ within a transition frequency range at a transition between two neighboring subbands of the resulting analysis and/or synthesis filter bank (101, 102); and/or
   the lobe width term is dependent on an integral of the energy of the frequency response of the prototype filter p₀ across the transition frequency range.
EEE4. The method (200) of any of EEE2 to EEE3, wherein the lobe width term is dependent on or corresponds to

$${e}_{m} = \frac{1}{π} {\int }_{\frac{π}{M}}^{\frac{2 π}{M}} {\vert {P}_{0} ( {e}^{j ω} ) \vert}^{2} d ω$$

with P₀(e^{jω}) being a frequency response of the prototype filter p₀, and with

$$[ \frac{π}{M} , \frac{2 π}{M} ]$$

being a transition frequency range between two neighboring subbands of the resulting analysis and/or synthesis filter bank (101, 102).
EEE5. The method (200) of any of EEE2 to EEE4, wherein the composite objective function eₜₒₜ comprises a weighted sum of the lobe width term eₘ, the transfer function error term eₜ and the aliasing error term eₐ.
EEE6. The method (200) of any previous EEE, wherein the N coefficients of the asymmetric prototype filter p₀ that reduce the composite objective function eₜₒₜ are determined using an auxiliary decimation factor which is greater than the decimation factor S that is used by the analysis and/or synthesis filter bank (101, 102) during deployment of the analysis and/or synthesis filter bank (101, 102).
EEE7. The method (200) of any previous EEE, wherein
   the composite objective function eₜₒₜ comprises a ripple term eₛ in addition to the transfer function error term eₜ and the aliasing error term eₐ; and
   the ripple term is directed at limiting and/or reducing a frequency response ripple, in particular a shoot over, in a pass band of the prototype filter p₀.
EEE8. The method (200) of EEE7, wherein
   the ripple term is dependent on an energy deviation of a frequency response of the prototype filter p₀ within a pass band range from the frequency response at a mid frequency of the pass band, in particular from a scaled frequency response at the mid frequency of the pass band; and/or
   the ripple term is dependent on an integral of the energy deviation of the frequency response of the prototype filter p₀ across the pass band range from the frequency response at the mid frequency of the pass band.
EEE9. The method (200) of any of EEE7 to EEE8, wherein the ripple term is dependent on or corresponds to

$${e}_{s} = \frac{1}{π} {\int }_{0}^{\frac{π}{M}} {( \vert {P}_{0} ( ω ) \vert - γ \vert {P}_{0} ( 0 ) \vert )}_{+}^{2} d ω$$

with P₀(ω) being a frequency response of the prototype filter p₀, with

$$[ 0 , \frac{π}{M} ]$$

being a frequency range, in particular a half, of a pass band of the frequency response of the prototype filter p₀, with P₀(0) being the frequency response of the prototype filter p₀ at a mid frequency ω=0 of the pass band, with γ being a scaling factor controlling an amount of ripple, and with (⋅)₊ being an operator which limits the expression within the operator to positive values.
EEE10. The method (200) of any of EEE7 to EEE9, wherein the composite objective function eₜₒₜ comprises a weighted sum of the ripple term eₛ, the transfer function error term eₜ and the aliasing error term eₐ.
EEE11. The method (200) of any of EEE7 to EEE9 referring back to EEE2 to EEE5, wherein the composite objective function eₜₒₜ comprises a weighted sum of the ripple term eₛ, the transfer function error term eₜ, the aliasing error term eₐ and the lobe width term eₘ.

EEE12. The method (200) of any previous EEE, wherein the step of determining (202) the composite objective function eₜₒₜ and the step of determining (203) the N coefficients of the asymmetric prototype filter p₀ are repeated iteratively, until a minimum of the composite objective function eₜₒₜ is reached.
EEE13. The method (200) of EEE11, wherein
   the step of determining (202) the composite objective function eₜₒₜ comprises determining a value for the composite objective function eₜₒₜ for given coefficients of the prototype filter p₀; and
   the step of determining (203) the N coefficients of the asymmetric prototype filter p₀ comprises determining updated coefficients of the prototype filter p₀ based on a derivative or an estimate of a derivative of the composite objective function eₜₒₜ with respect to the coefficients of the prototype filter p₀.
EEE14. The method (200) of any previous EEE, further comprising
   configuring (204) the asymmetric prototype filter p₀ using the N coefficients; and
   applying (205) the configured asymmetric prototype filter p₀ to an audio signal.
EEE15. The method (200) of any previous EEE, further comprising
   generating the analysis filters hₖ and the synthesis filters fₖ of the analysis and/or synthesis filter bank (101. 102) based on the N coefficients of the prototype filter p₀ using cosine modulation, sine modulation and/or complex-exponential modulation; and/or
   processing an audio signal using the analysis and/or synthesis filter bank (101, 102).
EEE16. A device for determining N coefficients of an asymmetric prototype filter p₀ for use in an M-channel analysis and/or synthesis filter bank (101, 102) comprising M analysis filters hₖ (103) and/or M synthesis filters fₖ (106), k=0, . . . , M−1, wherein M is greater than 1, and wherein subband signals which are processed by the analysis and/or synthesis filter bank (101, 102) are decimated by a decimation factor S, with S<M, the device is configured to
   determine a target transfer function of the analysis and/or synthesis filter bank (101, 102) comprising a target delay D; wherein D is smaller or equal to N;
   determine a composite objective function eₜₒₜ comprising a transfer function error term eₜ and an aliasing error term eₐ; wherein the transfer function error term eₜ is associated with a deviation between a transfer function of the analysis and/or synthesis filter bank (101, 102) and the target transfer function; and wherein the aliasing error term eₐ is associated with errors incurred due to the decimation and/or interpolation of the subband signals which are processed by the analysis and/or synthesis filter bank (101, 102); and
   determine N coefficients of the asymmetric prototype filter p₀ that reduce, in particular minimize, the composite objective function eₜₒₜ.
EEE17. A system configured to process an audio signal, comprising:
   one or more processors; and
   a non-transitory computer-readable medium storing instructions that, when executed by the one or more processors, cause the one or more processors to perform operations of the method according to any of EEE1 to EEE15.
EEE18. A method for processing an audio signal, the method comprising,
   determining a plurality of subband signals by filtering the audio signal with M analysis filters (103) of an oversampled analysis filter bank (101);
   processing the plurality of subband signals to generate a plurality of processed subband signals; and
   determining a processed audio signal by filtering the plurality of processed subband signals with M synthesis filters (106) of an oversampled synthesis filter bank (102); wherein the M analysis filters (103) and the M synthesis filters (106) are modulated versions of an asymmetric prototype filter p₀ determined using the method (200) according to EEE1 to EEE15.
EEE19. An audio signal processing device for processing an audio signal, wherein the audio processing device is configured to,
   determine a plurality of subband signals by filtering the audio signal with M analysis filters (103) of an oversampled analysis filter bank (101);
   process the plurality of subband signals to generate a plurality of processed subband signals; and
   determine a processed audio signal by filtering the plurality of processed subband signals with M synthesis filters (106) of an oversampled synthesis filter bank (102); wherein the M analysis filters (103) and the M synthesis filters (106) are modulated versions of an asymmetric prototype filter p₀ determined using the method (200) according to EEE1 to EEE15.
EEE20. A non-transitory computer-readable medium storing instructions that, when executed by one or more processors, cause the one or more processors to perform operations of any of EEE1 to EEE15 and EEE18.

1-20. (canceled)

21. A method for determining N coefficients of an asymmetric prototype filter p₀ for use in an M-channel analysis and/or synthesis filter bank, the method comprising:
determining a target transfer function of an analysis and/or synthesis filter bank comprising a target delay D, wherein D is smaller or equal to N;
determining a composite objective function eₜₒₜ comprising a transfer function error term eₜ and an aliasing error term eₐ, wherein the transfer function error term eₜ is associated with a deviation between a transfer function of the analysis and/or synthesis filter bank and the target transfer function, and wherein the aliasing error term eₐ is associated with errors incurred due to the decimation and/or interpolation of the subband signals which are processed by the analysis and/or synthesis filter bank; and
determining N coefficients of the asymmetric prototype filter p₀ that reduce, in particular minimize, the composite objective function eₜₒₜ.

22. The method of claim 21, wherein:
the composite objective function eₜₒₜ comprises a lobe width term eₘ in addition to the transfer function error term eₜ and the aliasing error term eₐ; and
the lobe width term is directed at reducing a width of a main lobe of the prototype filter p₀.

23. The method of claim 22, wherein:
the lobe width term is dependent on an energy of a frequency response of the prototype filter p₀ within a transition frequency range at a transition between two neighboring subbands of the resulting analysis and/or synthesis filter bank; and/or
the lobe width term is dependent on an integral of the energy of the frequency response of the prototype filter p₀ across the transition frequency range.

24. The method of claim 22, wherein the lobe width term is dependent on or corresponds to
$${e}_{m} = \frac{1}{π} {\int }_{\frac{π}{M}}^{\frac{2 π}{M}} {\vert {P}_{0} ( {e}^{j ω} ) \vert}^{2} d ω$$
with P₀(e^{jω}) being a frequency response of the prototype filter p₀, and with
$$[ \frac{π}{M} , \frac{2 π}{M} ]$$
being a transition frequency range between two neighboring subbands of the resulting analysis and/or synthesis filter bank.

25. The method of claim 24, wherein the composite objective function eₜₒₜ comprises a weighted sum of the lobe width term eₘ, the transfer function error term eₜ and the aliasing error term eₐ.

26. The method of claim 21, wherein the N coefficients of the asymmetric prototype filter p₀ that reduce the composite objective function eₜₒₜ are determined using an auxiliary decimation factor which is greater than the decimation factor S that is used by the analysis and/or synthesis filter bank during deployment of the analysis and/or synthesis filter bank.

27. The method of claim 21, wherein:
the composite objective function eₜₒₜ comprises a ripple term eₛ in addition to the transfer function error term eₜ and the aliasing error term eₐ; and
the ripple term is directed at limiting and/or reducing a frequency response ripple, in particular a shoot over, in a pass band of the prototype filter p₀.

28. The method of claim 27, wherein:
the ripple term is dependent on an energy deviation of a frequency response of the prototype filter p₀ within a pass band range from the frequency response at a mid frequency of the pass band, in particular from a scaled frequency response at the mid frequency of the pass band; and/or
the ripple term is dependent on an integral of the energy deviation of the frequency response of the prototype filter p₀ across the pass band range from the frequency response at the mid frequency of the pass band.

29. The method of claim 27, wherein the ripple term is dependent on or corresponds to
$${e}_{s} = \frac{1}{π} {\int }_{0}^{\frac{π}{M}} {( \vert {P}_{0} ( ω ) \vert - γ \vert {P}_{0} ( 0 ) \vert )}_{+}^{2} d ω$$
with P₀(ω) being a frequency response of the prototype filter p₀, with
$$[ 0 , \frac{π}{M} ]$$
being a frequency range, in particular a half, of a pass band of the frequency response of the prototype filter p₀, with P₀(0) being the frequency response of the prototype filter p₀ at a mid frequency ω=0 of the pass band,
with γ being a scaling factor controlling an amount of ripple, and
with (⋅)₊ being an operator which limits the expression within the operator to positive values.

30. The method of claim 27, wherein the composite objective function eₜₒₜ comprises a weighted sum of the ripple term eₛ, the transfer function error term eₜ and the aliasing error term eₐ.

31. The method of claim 27, wherein the composite objective function eₜₒₜ comprises a weighted sum of the ripple term eₛ, the transfer function error term eₜ, the aliasing error term eₐ and the lobe width term eₘ.

32. The method of claim 21, wherein the step of determining the composite objective function eₜₒₜ and the step of determining the N coefficients of the asymmetric prototype filter p₀ are repeated iteratively, until a minimum of the composite objective function eₜₒₜ is reached.

33. The method of claim 31, wherein:
the step of determining the composite objective function eₜₒₜ comprises determining a value for the composite objective function eₜₒₜ for given coefficients of the prototype filter p₀; and
the step of determining the N coefficients of the asymmetric prototype filter p₀ comprises determining updated coefficients of the prototype filter p₀ based on a derivative or an estimate of a derivative of the composite objective function eₜₒₜ with respect to the coefficients of the prototype filter p₀.

34. The method of claim 21, further comprising:
configuring the asymmetric prototype filter p₀ using the N coefficients; and
applying the configured asymmetric prototype filter p₀ to an audio signal.

35. The method of claim 21, further comprising:
generating the analysis filters hₖ and the synthesis filters fₖ of the analysis and/or synthesis filter bank based on the N coefficients of the prototype filter p₀ using cosine modulation, sine modulation and/or complex-exponential modulation; and/or
an audio signal using the analysis and/or synthesis filter bank.

36. A device for determining N coefficients of an asymmetric prototype filter p₀ for use in an M-channel analysis and/or synthesis filter bank, the device is configured to:
determine a target transfer function of the analysis and/or synthesis filter bank comprising a target delay D; wherein D is smaller or equal to N;
determine a composite objective function eₜₒₜ comprising a transfer function error term eₜ and an aliasing error term eₐ; wherein the transfer function error term eₜ is associated with a deviation between a transfer function of the analysis and/or synthesis filter bank and the target transfer function; and wherein the aliasing error term eₐ is associated with errors incurred due to the decimation and/or interpolation of the subband signals which are processed by the analysis and/or synthesis filter bank; and
determine N coefficients of the asymmetric prototype filter p₀ that reduce, in particular minimize, the composite objective function eₜₒₜ.

37. A system configured to process an audio signal, comprising:
one or more processors; and
a non-transitory computer-readable medium storing instructions that, when executed by the one or more processors, cause the one or more processors to perform operations of the method according to claim 21.

38. A method for processing an audio signal, the method comprising,
determining a plurality of subband signals by filtering the audio signal with M analysis filters of an oversampled analysis filter bank;
processing the plurality of subband signals to generate a plurality of processed subband signals; and
determining a processed audio signal by filtering the plurality of processed subband signals with M synthesis filters of an oversampled synthesis filter bank, wherein the M analysis filters and the M synthesis filters are modulated versions of an asymmetric prototype filter p₀ determined using the method according to claim 21.

39. An audio signal processing device for processing an audio signal, wherein the audio processing device is configured to:
determine a plurality of subband signals by filtering the audio signal with M analysis filters of an oversampled analysis filter bank;
process the plurality of subband signals to generate a plurality of processed subband signals; and
determine a processed audio signal by filtering the plurality of processed subband signals with M synthesis filters of an oversampled synthesis filter bank, wherein the M analysis filters and the M synthesis filters are modulated versions of an asymmetric prototype filter p₀ determined using the method according to claim 21.

40. A non-transitory computer-readable medium storing instructions that, when executed by one or more processors, cause the one or more processors to perform operations of claim 1.
